(19) United States
(12) Patent Application Publication
(10) Pub. No.: US 2019/0254190 A1
(43) Pub. Date: Aug. 15, 2019

(54) HANDHELD COMMUNICATION DEVICE AND THIN HEAT DISSIPATING STRUCTURE THEREOF

(71) Applicant: SY-THERMAL INC., New Taipei City (TW)

(72) Inventors: Fuh-Yuarn SHIAU, New Taipei City (TW); Chao-Chen KUO, New Taipei City (TW)

(21) Appl. No.: 16/272,684

(22) Filed: Feb. 11, 2019

(30) Foreign Application Priority Data
Feb. 13, 2018 (TW) 107202288

(51) Int. Cl. H05K 7/20; F28D 15/02; F28D 15/04; H01L 23/427

(52) U.S. Cl. CPC H05K 7/205; H05K 7/20336; H01L 23/427; F28D 15/04; F28D 15/0233

(57) ABSTRACT

A handheld communication device and a thin heat dissipating structure are provided. The thin heat dissipating structure includes: a heat conducting plate, having a top surface, a bottom surface and a penetrated slot, wherein an inner annular wall is formed in the penetrated slot, and convex pieces are oppositely extended from the inner annular wall and the bottom surface; and a heat pipe, received in the penetrated slot and latched and positioned by the convex pieces; a flat surface is defined by the heat pipe, the convex pieces and the bottom surface; the top surface is formed with at least one pair of punching recesses at two sides of the penetrated slot, so that two sides of the inner annular wall and the top surface are squeezed and deformed so as to form protrusions where the heat pipe is latched and positioned.

### BACKGROUND OF THE INVENTION

### Field of the Invention

The present invention relates to a heat dissipating structure, especially to a handheld communication device and a thin heat dissipating structure thereof.

### Description of Related Art

The calculating capacity and efficiency of a handheld communication device, for example a mobile phone, a tablet computer, a personal digital assistant (PDA) and a global positioning system (GPS), has been rapidly increasing, thus an internal component, for example a central process unit or an integrated circuit, would generate high temperature while being operated, if the internal component has stayed in a high temperature environment for a period of time, the internal component may be damaged. As such, heat accumulated in the internal component has to be dissipated for allowing the operation efficiency of the handheld communication device to be kept and enabling the service life thereof not to be affected.

A conventional heat dissipating structure adopted in the handheld communication device mainly includes a heat conducting plate which is made of a high heat conduction metal material, for example copper or aluminum; the heat conducting plate is directly arranged to be thermally adjacent to the internal component, for example the central process unit or the integrated circuit, so that heat generated by the internal component can be transferred to the heat conducting plate for allowing the heat to be dissipated to an external environment via the heat conducting plate. However, the heat dissipating speed of the conventional heat conducting plate is unable to meet up with the heat generating speed of the internal component.

Accordingly, the applicant of the present invention has devoted himself for improving the mentioned disadvantages.

### SUMMARY OF THE INVENTION

The present invention is to provide a handheld communication device and a thin heat dissipating structure thereof, in which a heat pipe and a heat conducting plate are arranged to be thermally adjacent to a heat generating unit for dissipating heat generated by the heat generating unit, so that the heat can be prevented from being accumulated in the heat generating unit, and an effect of increasing the heat dissipating efficiency can be achieved.

Accordingly, the present invention provides a thin heat dissipating structure, which includes: a heat conducting plate, having a top surface, a bottom surface and a penetrated slot penetrating the top surface and the bottom surface, wherein an inner annular wall is formed at an inner periphery of the penetrated slot, and two convex pieces are oppositely extended from the inner annular wall and the bottom surface; and a heat pipe, received in the penetrated slot and latched and positioned by the two convex pieces, wherein a flat surface is defined by the heat pipe, the two convex pieces and the bottom surface; wherein, the top surface of the heat conducting plate is formed with at least one pair of punching recesses at two sides of the penetrated slot with a punching means, so that two sides of the inner annular wall and the top surface are squeezed and deformed so as to form two protrusions, and the heat pipe is latched and positioned by the two protrusions.

Accordingly, the present invention provides a handheld communication device, which includes: a casing, formed with a chamber therein; a heat generating unit, received in the chamber; and the above-mentioned thin heat dissipating structure, received in the chamber, wherein the heat pipe is arranged to be thermally adjacent to the heat generating unit.

Based on what has been mentioned above, the heat pipe is received in the penetrated slot, a lower portion of the heat pipe is latched and positioned by the convex pieces, the top surface of the heat conducting plate is formed with the punching recesses at the two sides of the penetrated slot with the punching means, so that the two sides of the inner annular wall and the top surface are squeezed and deformed so as to form the protrusions, an upper portion of the heat pipe is latched and positioned by the protrusions, so that the heat pipe can be rapidly assembly and stably positioned in the penetrated slot; thus, the assembling convenience and the structural stability of the thin heat dissipating structure can be enhanced.

Based on what has been mentioned above, a top portion of the convex piece is formed with an arc-shaped inclined surface, and a thickness of each of the convex pieces is gradually decreased toward a direction away from the inner annular wall, so that the shape of the convex piece itself can be matched with the shape of the heat pipe so as to be tightly adjacent to each other, and when the heat pipe is disposed in the penetrated slot, the heat pipe can be mutually mounted with the convex pieces and latched and positioned by the convex pieces without being deformed by an external force; thus, an objective of maintaining the original shape of the heat pipe can be achieved, situations of a capillary tissue inside the heat pipe being deformed, displaced or damaged can be avoided, and the excellent heat dissipating capacity of the heat pipe can be kept.

### BRIEF DESCRIPTION OF DRAWING

FIG. 1 is a perspective exploded view showing a handheld communication device according to the present invention;

FIG. 2 is a perspective exploded view showing a thin heat dissipating structure according to the present invention;

FIG. 3 is a cross sectional view showing the assembly of the thin heat dissipating structure according to the present invention;

FIG. 4 is a partially-enlarged cross sectional view showing the thin heat dissipating structure according to the present invention;

FIG. 5 is a perspective view showing the assembly of the handheld communication device according to the present invention;

FIG. 6 is a cross sectional view showing the assembly of the handheld communication device according to the present invention; and

FIG. 7 is a schematic view showing an operating status of the handheld communication device according to the present invention.

### DETAILED DESCRIPTION OF THE INVENTION

A preferred embodiment of the present invention will be described with reference to the drawings.

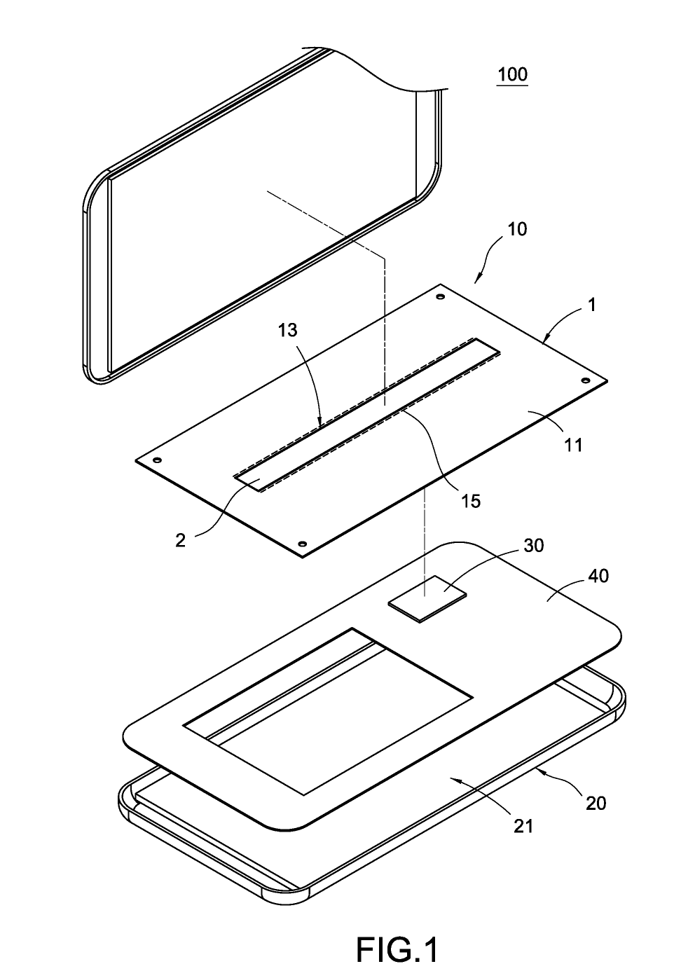

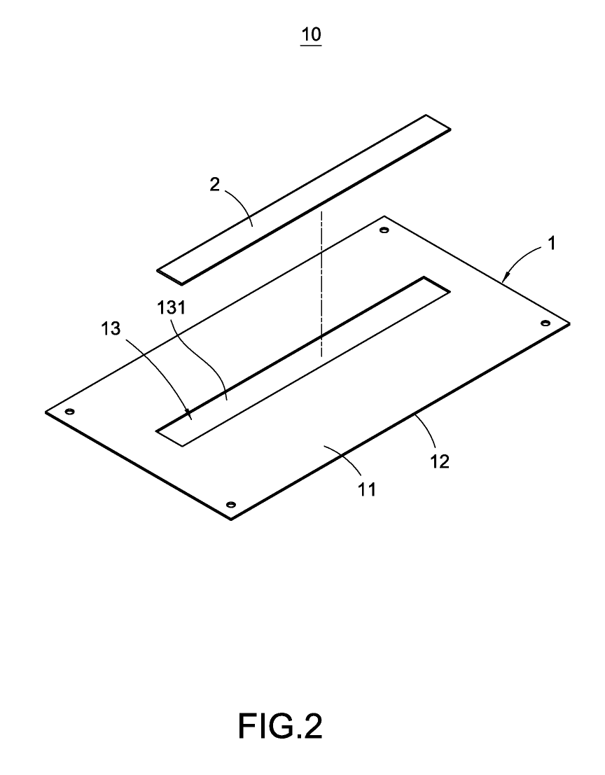

Please refer from FIG. 1 to FIG. 7, a handheld communication device and a thin heat dissipating structure are provided by the present invention. The handheld communication device 100 mainly includes a casing 20, a heat generating unit 30 and a thin heat dissipating structure 10; and the thin heat dissipating structure 10 mainly includes a heat conducting plate 1 and a heat pipe 2.

As shown from FIG. 1 to FIG. 7, the heat conducting plate 1 has a top surface 11, a bottom surface 12 and a penetrated slot 13 penetrating the top surface 11 and the bottom surface 12. An inner annular wall 131 is formed at an inner periphery of the penetrated slot 13, two convex pieces 14 are oppositely extended from the inner annular wall 131 and the bottom surface 12, a top portion of each of the convex pieces 14 is formed with an arc-shaped inclined surface 141, and a thickness of each of the convex pieces 14 is gradually decreased toward a direction away from the inner annular wall 131.

As shown from FIG. 1 to FIG. 7, the heat pipe 2 is received in the penetrated slot 13 and a lower portion of the heat pipe 2 is latched and positioned by the two convex pieces 14. The top surface 11 of the heat conducting plate 1 is formed with one or plural pairs of punching recesses 15 at two sides of the penetrated slot 13 with a punching means, so that two sides of the inner annular wall 131 and the top surface 11 are squeezed and deformed so as to form two protrusions 16, an upper portion of the heat pipe 2 is latched and positioned by the two protrusions 16, and a flat surface S is defined by the heat pipe 2, the two convex pieces 14 and the bottom surface 12, in other words the lower portion the heat pipe 2, bottom portions of the two convex pieces 14 and the bottom surface 12 of the heat conducting plate 1 are located on a same planar surface, so that a surface of the heat generating unit 30 is able to be more easily and tightly arranged to be adjacent to the flat surface S, thereby increasing the heat dissipating efficiency of the thin heat dissipating structure 10.

According to this embodiment, there are plural pairs of the punching recesses 15, but what shall be addressed is that the scope of the present invention is not limited to the above-mentioned arrangement, and the plural pairs of punching recesses 15 are disposed at two sides of the penetrated slot 13 and arranged with intervals and in parallel with each other.

Moreover, the heat pipe 2 is consisted of a flat pipe body made of a good heat conducting material, for example copper or aluminum, and a capillary tissue disposed inside the flat pipe body, wherein the capillary tissue is composed of sintered powers, woven nets, fibers, grooves or a combination of the above.

According to this embodiment, a thickness h2 of the heat pipe 2 is equal to or smaller than a thickness h1 of the heat conducting plate 1, so that an advantage of being thinned is provided to the thin heat dissipating structure 10, and effects of being small and thin, occupying less space and easy to be assembled are also provided to the thin heat dissipating structure 10. Where, the thickness h1 of the heat conducting plate 1 is between 0.3 to 0.6 mm, but what shall be addressed is that the scope of the present invention is not limited to the above-mentioned arrangement.

Moreover, the shape of the penetrated slot 13 is matched with the shape of the heat pipe 2, the penetrated slot 13 can be formed in any geometrical shape, for example, a flat-shape, an L-shape or a U-shape, the heat pipe 2 can be formed as a flat-shaped pipe member, an L-shaped pipe member or a U-shaped pipe member, but what shall be addressed is that the scope of the present invention is not limited to the above-mentioned arrangement.

The thin heat dissipating structure 10 provided by the present invention further includes a heat dissipating paste (not shown in figures), the heat dissipating paste (not shown in figures) is filled between the heat pipe 2, the inner annular wall 131, the two convex pieces 14 and the two protrusions 16, so that a heat conducting area between the heat pipe 2, the inner annular wall 131, the two convex pieces 14 and the two protrusions 16 can be enlarged, what shall be addressed is that the heat dissipating paste is not a necessary component of the thin heat dissipating structure 10, thus the heat dissipating paste can be optionally provided according to actual needs.

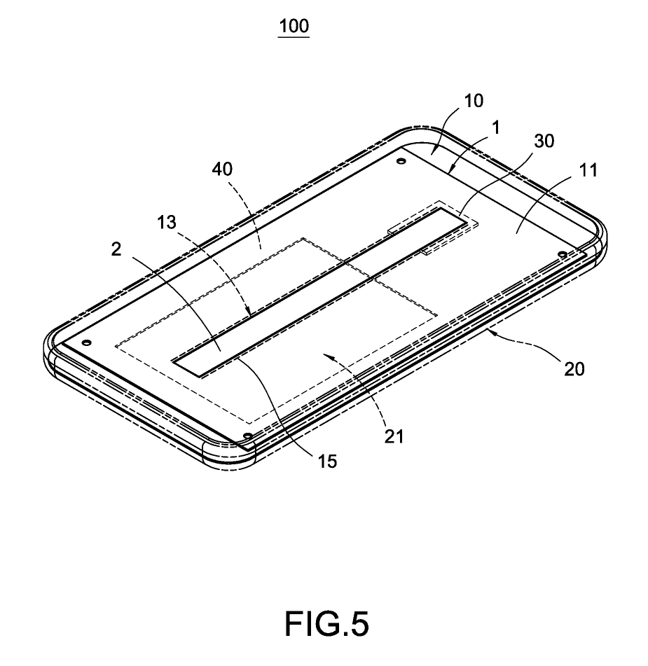

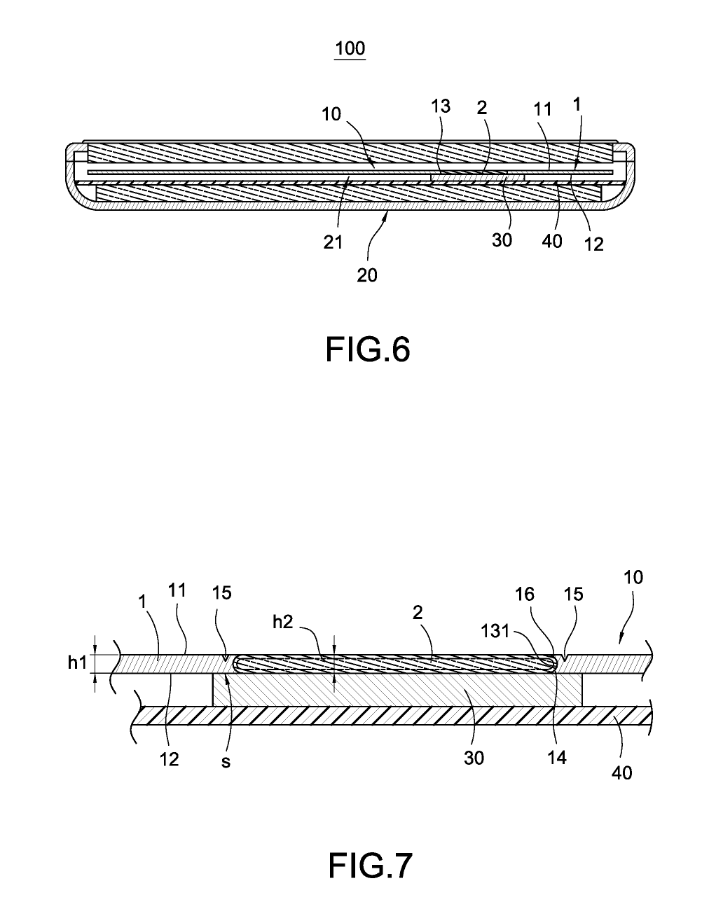

As shown in FIG. 1, FIG. 5, FIG. 6 and FIG. 7, a chamber 21 is formed inside the casing 20. Details are provided as follows. The casing 20 is consisted of an upper casing member and a lower casing member being engaged, the chamber 21 is formed inside the upper casing member and the lower casing member, a component, for example a central process unit and an integrated circuit, can be adopted as the heat generating unit 30, but what shall be address is that the scope of the present invention is not limited to the above-mentioned components. The heat generating unit 30 is disposed on a circuit board 40, the heat generating unit 30 and the circuit board 40 are both disposed inside the chamber 21, and the circuit board 40 and the heat conducting plate 1 are arranged in a stacked means.

The thin heat dissipating structure 10 is disposed inside the chamber 21, and the heat pipe 2 is arranged to be thermally adjacent to the heat generating unit 30. Wherein, the heat conducting plate 1 and the convex pieces 14 can be arranged to be thermally adjacent to the heat generating unit 30 or not, in other words a thermal adjacent surface defined between the heat conducting plate 1, the convex pieces 14 and the heat generating unit 30 can be adjusted with respect to the dimension of the heat generating unit 30.

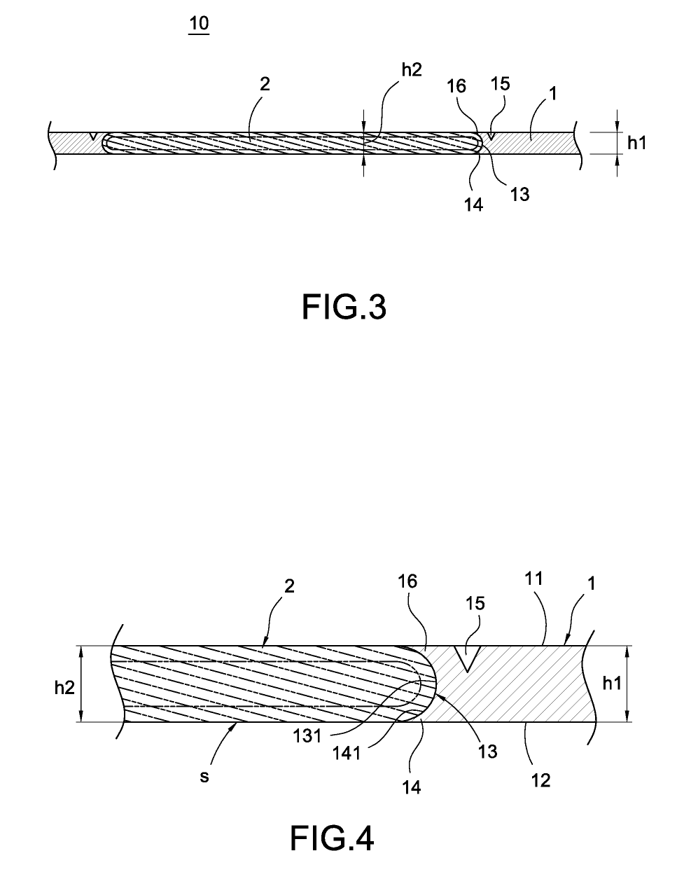

As shown from FIG. 3 to FIG. 7, which disclose an operating status of the handheld communication device 100 and the thin heat dissipating structure 10 according to the present invention. The heat pipe 2 is arranged to be thermally adjacent to the heat generating unit 30, heat generated by the heat generating unit 30 is evenly transferred to the heat conducting plate 1 via the heat pipe 2, so that the heat can be prevented from being accumulated in the heat generating unit 30 and a periphery thereof, and the heat dissipating efficiency of the thin heat dissipating structure 10 can be increased.

According to this embodiment, the heat pipe 2 is received in the penetrated slot 13, the lower portion of the heat pipe 2 is latched and positioned by the convex pieces 14, the top surface 11 of the heat conducting plate 1 is formed with the punching recesses 15 at the two sides of the penetrated slot 13 with the punching means, so that the two sides of the inner annular wall 131 and the top surface 11 are squeezed and deformed towards the direction of the heat pipe 2 so as to form the two protrusions 16, the upper portion of the heat pipe 2 is latched and positioned by the protrusions 16, so that the heat pipe 2 can be rapidly assembly and stably positioned in the penetrated slot 13; thus, a tight contact required by a transversal heat conduction can be improved, and the assembling convenience, the structural stability and the heat dissipating efficiency of the thin heat dissipating structure 10 can be enhanced.

Moreover, the top portion of the convex piece 14 is formed with the arc-shaped inclined surface 141, and the thickness of each of the convex pieces 14 is gradually decreased toward the direction away from the inner annular wall 131, so that the shape of the convex piece 14 itself can be matched with the shape of the heat pipe 2 so as to be tightly adjacent to each other, and when the heat pipe 2 is disposed in the penetrated slot 13, the heat pipe 2 can be mutually mounted with the convex pieces 14 and latched and positioned by the convex pieces 14 without being deformed by an external force; thus, an objective of maintaining the original shape of the heat pipe 2 can be achieved, situations of the capillary tissue inside the heat pipe 2 being deformed, displaced or damaged can be avoided, and the excellent heat dissipating capacity of the heat pipe 2 can be kept. Accordingly, the handheld communication device 100 and the thin heat dissipating structure 10 thereof provided by the present invention is novel and more practical in use comparing to prior arts.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A thin heat dissipating structure, including:
a heat conducting plate, having a top surface, a bottom surface and a penetrated slot penetrating the top surface and the bottom surface, wherein an inner annular wall is formed at an inner periphery of the penetrated slot, and two convex pieces are oppositely extended from the inner annular wall and the bottom surface; and
a heat pipe, received in the penetrated slot and latched and positioned by the two convex pieces, wherein a flat surface is defined by the heat pipe, the two convex pieces and the bottom surface;
wherein, the top surface of the heat conducting plate is formed with at least one pair of punching recesses at two sides of the penetrated slot with a punching means, so that two sides of the inner annular wall and the top surface are squeezed and deformed so as to form two protrusions, and the heat pipe is latched and positioned by the two protrusions.

2. The thin heat dissipating structure according to claim 1, wherein there are plural pairs of the punching recesses, and the plural pairs of punching recesses are disposed at two sides of the penetrated slot and arranged with intervals and in parallel with each other.

3. The thin heat dissipating structure according to claim 1, wherein a top portion of each of the convex pieces is formed with an arc-shaped inclined surface, and a thickness of each of the convex pieces is gradually decreased toward a direction away from the inner annular wall.

4. The thin heat dissipating structure according to claim 3, wherein a thickness of the heat pipe is equal to or smaller than a thickness of the heat conducting plate.

5. The thin heat dissipating structure according to claim 4, further including a heat dissipating paste, and the heat dissipating paste is filled between the heat pipe, the inner annular wall, the two convex pieces and the two protrusions.

6. The thin heat dissipating structure according to claim 5, wherein the heat pipe is formed as a flat-shaped pipe member, an L-shaped pipe member or a U-shaped pipe member, and the penetrated slot is formed with a shape matched with the shape of the heat pipe.

7. A handheld communication device, including:
a casing, formed with a chamber therein;
a heat generating unit, received in the chamber; and
a thin heat dissipating structure, received in the chamber and including:
a heat conducting plate, having a top surface, a bottom surface and a penetrated slot penetrating the top surface and the bottom surface, wherein an inner annular wall is formed at an inner periphery of the penetrated slot, and two convex pieces are oppositely extended from the inner annular wall and the bottom surface; and
a heat pipe, received in the penetrated slot and latched and positioned by the two convex pieces, wherein a flat surface is defined by the heat pipe, the two convex pieces and the bottom surface;
wherein, the top surface of the heat conducting plate is formed with at least one pair of punching recesses at two sides of the penetrated slot with a punching means, so that two sides of the inner annular wall and the top surface are squeezed and deformed so as to form two protrusions, the heat pipe is latched and positioned by the two protrusions, and the heat pipe is arranged to be thermally adjacent to the heat generating unit.

8. The handheld communication device according to claim 7, wherein the bottom surface of the heat conducting plate and the two convex pieces are arranged to be thermally adjacent to the heat generating unit.

9. The handheld communication device according to claim 7, wherein there are plural pairs of the punching recesses, and the plural pairs of punching recesses are disposed at two sides of the penetrated slot and arranged with intervals and in parallel with each other.

10. The handheld communication device according to claim 7, wherein a top portion of each of the convex pieces is formed with an arc-shaped inclined surface, and a thickness of each of the convex pieces is gradually decreased toward a direction away from the inner annular wall.

11. The handheld communication device according to claim 10, wherein a thickness of the heat pipe is equal to or smaller than a thickness of the heat conducting plate.

12. The handheld communication device according to claim 11, further including a heat dissipating paste, and the heat dissipating paste is filled between the heat pipe, the inner annular wall, the two convex pieces and the two protrusions.

13. The handheld communication device according to claim 12, wherein the heat pipe is formed as a flat-shaped pipe member, an L-shaped pipe member or a U-shaped pipe member, and the penetrated slot is formed with a shape matched with the shape of the heat pipe.
